(19) United States
(12) Patent Application Publication
(10) Pub. No.: US 2026/0344365 A1
(43) Pub. Date: Oct. 29, 2026

(54) METHOD OF SELECTING VAPOR DEPOSITION PROCESS PARAMETERS

(71) Applicant: ASM IP Holding B.V., Almere (NL)

(72) Inventors: Quentin Nikitas Nicolas Lionel Eric Tricas, Schaerbeek (BE); Werner Knaepen, Leuven (BE)

(21) Appl. No.: 19/657,437

(22) Filed: Apr. 24, 2026

Related U.S. Application Data
(60) Provisional application No. 63/796,923, filed on Apr. 29, 2025.

(51) Int. Cl. H10P 74/20; C23C 16/04; C23C 16/455; C23C 16/52; H10P 14/60

(52) U.S. Cl. CPC H10P 74/203; C23C 16/045; C23C 16/45544; C23C 16/52; H10P 14/6339

(57) ABSTRACT

The present invention relates to methods and assemblies for selecting a set of process parameters for vapor depositing layers on structured semiconductor substrates. One or more test runs is performed, each test run being associated with a set of test process parameter. Each test run comprises vapor depositing, applying the associated set of test process parameter, a test layer on a surface of a porous material of each of one or more test substrates. The deposited test layer of each of the one or more test substrates of each of the one or more test runs is analysed for determining an effect of the set of test process parameters on the deposited test layer. Based on said analysis, the set of process parameters for said process for vapor depositing the layer on the surface of the structured semiconductor substrate is selected.

### CROSS-REFERENCE TO RELATED APPLICATIONS

This application claims priority to U.S. Provisional Patent Application Ser. No. 63/796,923 filed Apr. 29, 2025 titled METHOD OF SELECTING VAPOR DEPOSITION PROCESS PARAMETERS, the disclosure of which is hereby incorporated by reference in its entirety.

### TECHNICAL FIELD OF THE INVENTION

The present invention relates to the field of semiconductor device manufacturing, and more specifically to vapor deposition on structured semiconductor substrates.

### BACKGROUND OF THE INVENTION

Semiconductor manufacturing processes continue to evolve toward creating increasingly complex structures with ever-smaller feature dimensions. Among these processes, vapor deposition methods, including chemical vapor deposition (CVD), e.g., atomic layer deposition (ALD), play crucial roles in forming the thin films required for modern semiconductor devices. As device architectures have progressed from simple planar structures to complex three-dimensional configurations with high aspect ratio features, the challenges associated with achieving uniform, conformal deposition have intensified.

The development and optimization of vapor deposition processes for advanced semiconductor structures typically require extensive experimentation. This process development phase is particularly demanding for structured semiconductor substrates that have high surface area enhancement ratios, such as those found in vertical NAND (VNAND) memory and other advanced devices. These structured semiconductor substrates often contain nanoscale voids, trenches, and features with extremely high aspect ratios, creating significant surface area enhancement compared to flat surfaces.

For such structured semiconductor substrates, process parameter optimization presents a range of complications. Factors such as temperature, pressure, precursor types, pulse timing, and gas flow rates affect the deposited layer in complex ways that are difficult to predict, especially when dealing with high surface area enhancement structures. Gas transport phenomena in high surface area enhancement structures create additional challenges. The movement of precursor molecules and purge gases through narrow openings and complex pathways can be limited by diffusion, leading to non-uniform deposition. Precursor depletion effects can occur as reactants are consumed along their path through intricate structures, resulting in thickness variations that are difficult to predict with conventional test vehicles.

Indeed, traditional approaches to process development often rely on simplified test vehicles such as flat wafers or basic coupons, but these fail to adequately represent the complex geometries and gas flow dynamics present in production scenarios. The effects of process parameters on deposition uniformity can vary significantly between simplified test structures and actual product geometries. The disparity between test conditions and actual production environments can lead to unexpected challenges when scaling processes to high-volume manufacturing.

Alternatively, process development could be performed on costly product wafers, but this typically limits the number of experimental iterations possible due to economic constraints.

The semiconductor industry continuously strives to reduce development cycle times while improving process robustness. The gap between laboratory testing and high-volume manufacturing conditions represents a significant risk factor in technology development. More representative test methodologies could potentially reduce this risk, but developing such methodologies while maintaining cost-effectiveness remains challenging.

Challenges remain in developing efficient, economical methods for optimizing vapor deposition processes for complex semiconductor structures without requiring excessive use of valuable product wafers or accepting the limitations of overly simplified test vehicles.

### SUMMARY OF THE INVENTION

It is an objective of the present invention to provide good methods and assemblies for selecting a set of process parameter for a process for vapor depositing a layer on a surface of a structured semiconductor substrate.

The above objective is accomplished by a method and apparatus according to the present invention.

It is an advantage of embodiments of the present invention that the geometric structure of a structured semiconductor substrate is simulated in test runs by a porous material.

It is an advantage of embodiments of the present invention that the pores of the porous structure provide surface area enhancement. It is an advantage of embodiments of the present invention that the pores of the porous structure may provide a vapor flow path comparable to that of the structured semiconductor substrate.

It is an advantage of embodiments of the present invention that the pores may have dimensions comparable to void sizes on the structured semiconductor substrate. It is, therefore, an advantage of embodiments of the present invention that testing deposition processes on the porous material may provide a good simulation of deposition processes on the structured semiconductor substrates.

It is, furthermore, an advantage of embodiments of the present invention that a cheap and easy to manufacture test substrate may be provided. This may be especially advantageous in optimizing batch deposition processes, in which deposition may be performed on a stack of substrates (which may comprise, e.g., 150 wafers), wherein the deposition characteristics can vary for different wafers of the stack. For example, using a stack of 150 test substrates of the present invention for testing a set of process parameters for such a batch process may be considerably less expensive, than when a stack of 150 structured semiconductor substrates would be used, so that the present invention may provide strongly reduced costs of testing batch deposition processes.

In a first aspect, the present invention relates to a method of selecting a set of process parameters for a process for vapor depositing a layer on a surface of a structured semiconductor substrate, the method containing: performing one or more test runs, each test run being associated with a set of test process parameters, each test run comprising: vapor depositing, applying the associated set of test process parameters, a test layer on a surface of a porous material of each of one or more test substrates, and analysing the deposited test layer of each of the one or more test substrates of each of the one or more test runs for determining an effect of the set of test process parameters on the deposited test layer, and selecting, based on said analysis, the set of process parameters for said process for vapor depositing the layer on the surface of the structured semiconductor substrate.

In a second aspect, the present invention relates to a process of vapor depositing a layer on a surface of a structured semiconductor substrate, the method containing: selecting a set of process parameters using a method in accordance with the first aspect, and vapor depositing the layer on the surface of the structured semiconductor substrate using the selected set of process parameters.

In a third aspect, the present invention relates to an assembly comprising: a vapor deposition apparatus configured for performing one or more test runs, each test run being associated with a set of test process parameters, each test run comprising: vapor depositing, applying the associated set of test process parameters, a test layer on a surface of a porous material of each of one or more test substrates, and a device configured for analysing the deposited test layer of each of the one or more test substrates of each of the one or more test runs for determining an effect of the set of test process parameters on the deposited test layer, and a controller configured for selecting, based on said analysis, the set of process parameters for a process for vapor depositing a layer on a surface of a structured semiconductor substrate.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a flow diagram of a method for selecting a set of process parameters for vapor depositing a layer on a structured semiconductor substrate according to embodiments of the present invention.

FIG. 2 is a schematic representation of a vapor deposition apparatus with stacked test substrates in a process chamber according to embodiments of the present invention.

FIG. 3 is a cross-sectional view of a structured semiconductor substrate according to embodiments of the present invention.

FIG. 4 is a cross-sectional view of a test substrate containing a porous aluminum oxide layer according to embodiments of the present invention.

FIG. 5 is a cross-sectional view of a test substrate after a first test run showing a non-conformal deposited test layer according to embodiments of the present invention.

FIG. 6 is a cross-sectional view of a test substrate after a second test run showing conformal deposited test layer according to embodiments of the present invention.

FIG. 7 is a cross-sectional view of a structured semiconductor substrate after vapor deposition using a selected set of process parameters according to embodiments of the present invention.

In the different figures, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

The invention will now be described by a detailed description of several embodiments of the invention. It is clear that other embodiments of the invention can be configured according to the knowledge of persons skilled in the art without departing from the technical teaching of the invention, the invention being limited only by the terms of the appended claims.

In a first aspect, the present invention relates to a method of selecting a set of process parameters for a process for vapor depositing a layer on a surface of a structured semiconductor substrate, the method containing: performing one or more test runs, each test run being associated with a set of test process parameters, each test run comprising: vapor depositing, applying the associated set of test process parameters, a test layer on a surface of a porous material of each of one or more test substrates, and analysing the deposited test layer of each of the one or more test substrates of each of the one or more test runs for determining an effect of the set of test process parameters on the deposited test layer, and selecting, based on said analysis, the set of process parameters for said process for vapor depositing the layer on the surface of the structured semiconductor substrate.

In embodiments, the structured semiconductor substrate may be a semiconductor substrate that is structured, for example, that has already been partially processed. Typically, a next step in the processing of the structured semiconductor substrate may be the vapor deposition process, for which the layer is to be deposited on the surface of the structured semiconductor substrate, and for which a good set of process parameters is to be selected. In embodiments, the surface of the structured semiconductor substrate may contain any type of features that provide structure to the structured semiconductor substrate surface, such as devices, ridges, trenches, or holes, e.g., via holes or through holes. In embodiments, the structured semiconductor substrate may comprise a semiconductor device or an intermediate in the formation of a semiconductor device. For example, the semiconductor device may be any type of semiconductor device, such as a field-effect transistor or an intermediate thereto. These structures may enhance the surface area of the structured semiconductor substrate compared to a flat surface.

In embodiments, the pores may alternatively be called voids, holes, or channels. The porous material contains a plurality of pores, e.g., nanopores. In embodiments, the pores of the porous material may have a mean diameter of from 1 to 100 nanometers. The mean diameter may, for example, be determined using SEM or TEM analysis. This pore size range effectively mimics the dimensions of features in modern semiconductor devices. In embodiments, the pores of the porous material may have a mean depth of at least 1 micrometer. The mean depth may, for example, be determined using SEM or TEM analysis. This depth may provide a good simulation of high aspect ratio features that may be found in advanced semiconductor devices. The porous material may have highly porous, e.g., may have a porosity of from 1 to 60 v/v-% (with v/v-% indicating that this refers to the percentage of the volume of the porous material that is void or pore volume), such as from 10 to 50 v/v-%. The porosity may be determined by, for example, gravimetric analysis or mercury intrusion porosimetry.

In embodiments, the pores are exposed to the vapor of the vapor deposition process for depositing the test layer. The porous material typically contains a porous surface, containing entrances to the pores. Said vapor may enter the pores at the porous surface, and may flow through the pores, to be deposited on the surface of the pores. As such, the test layer may be deposited on surfaces of, i.e., inside, the pores. The test layer may be deposited on the porous surface of the test substrate. The test layer may be deposited on the porous surface of the test substrate and on surfaces of the pores.

The structured semiconductor substrate surface may be simulated or approximated by the pores, which typically enhance the surface area of the porous material. In embodiments, a surface area enhancement of a surface of the porous material may be at least 10×, preferably at least 50×, more preferably at least 100×, even more preferably at least 200×, with respect to a flat surface. The surface area enhancement of the porous material is a ratio of the surface area of the porous material, to the surface area of a flat, unmodified surface. The surface area of the porous material may be performed by performing a Brunauer-Emmett-Teller analysis on the porous surface of the porous material. In embodiments, a surface area enhancement of the porous material may be higher than a surface area enhancement of the structured semiconductor substrate.

In embodiments, the porous material may be any type of material that is porous, e.g., that contains a plurality of pores, such as a porous metal oxide (e.g., porous aluminium oxide), porous silicon, porous glass, and metal foams.

In preferred embodiments, the porous material may be porous aluminium oxide. In embodiments, the porous material is anodized aluminium oxide. In embodiments, the porous aluminium oxide is an aluminium oxide-based material that contains a distribution of pores extending into the oxide layer.

The porous aluminium oxide may be formed by anodizing aluminium. In particular, the process of forming porous aluminium oxide typically involves anodizing aluminium in an acidic electrolyte solution. During anodization, aluminium may be subjected to an electrochemical oxidation reaction, wherein the aluminium substrate may act as the anode. The electrolyte, typically consisting of sulfuric acid, phosphoric acid, or oxalic acid, facilitates the formation of a dense oxide layer on the aluminium surface. As the reaction progresses, a highly ordered porous structure may develop within the oxide layer, which is typically characterized by a uniform pore distribution and size. The pore size of porous aluminum oxide may be tuned by tuning the current and/or voltage applied during the anodization process. The pore depth of porous aluminum oxide may be tuned by tuning the duration of the applied current and/or voltage during the anodization process. This porous aluminium oxide layer typically exhibits increased surface area, mechanical strength, and chemical stability. Furthermore, porous aluminium oxide is cheap and easy to manufacture.

In embodiments, the test substrate may contain a support wafer, e.g., a silicon wafer, that may be covered by the porous aluminium oxide. In embodiments, the test substrate may contain a support wafer, e.g., a silicon wafer, covered by an aluminium substrate, that may, in turn, be covered by the porous aluminium oxide. The support wafer may be adapted to provide support to the porous aluminium oxide. Since aluminium typically melts at about 600 °C, it may be advantageous to provide the support wafer being the silicon wafer below the aluminium, to prevent bending at temperatures approaching the melting temperature. A drawback of using silicon wafers as support wafers is that the Al/Si interface may lower the melting temperature of the aluminium. In embodiments, the support wafer may be an aluminium substrate. In these embodiments, the test substrate may contain the aluminium substrate covered by the porous aluminium oxide.

The vapor deposition process used in the test runs is typically the same type of vapor deposition process for which the test runs are performed. In other words, the vapor deposition process used in the test runs is typically the same vapor deposition process as the vapor deposition process for depositing the layer on the structured semiconductor substrate. The vapor deposition process may be any process of forming a layer on a substrate by introducing one or more vapor-phase precursors or reactants, which may react or condense upon the substrate's surface to create the deposited material. In embodiments, the vapor deposition process may be chemical vapor deposition, such as atomic layer deposition. In embodiments, the vapor deposition process may be physical vapor deposition.

In embodiments, before depositing said test layer, the surface of the porous material (i.e., the surface on which the test layer is to be deposited) may be coated by a material of a type present at a surface of the structured semiconductor substrate. In embodiments, before depositing said test layer, the surface of the porous aluminium oxide may be coated by a material of a type present at a surface of the structured semiconductor substrate. In embodiments, the surface of the pores may be coated. In embodiments, the outer surface (e.g., the porous surface) of the porous material may be coated. Said vapor deposition of the test run may then deposit the test layer on the coated surface. These embodiments may allow for precise matching of the surface chemistry between the test substrate and the structured semiconductor substrate. For example, the structured semiconductor substrate may comprise a chemical species, such as TiN, SiOx, or AlN, different from the porous material. The test runs may then provide a good simulation of the deposition process on the structured semiconductor substrate if the surface is coated with this same chemical species. Any features of the coated porous material may be independently as described for corresponding features of the porous material. For example, the coated porous material is still porous (that is, the coating does not completely fill or block the pores), and sizes and depths of the pores of the coated porous material may be independently the same as described for the porous material.

In embodiments, the process for vapor depositing, e.g., for vapor depositing the layer and for depositing the test layer, may be chemical vapor deposition, preferably atomic layer deposition. These deposition techniques offer precise control over layer thickness and composition, essential for advanced semiconductor manufacturing.

In embodiments, each test run comprises providing the one or more test substrates into a process chamber. In embodiments, in each test run, a different set of test substrates may be used, so that each test run may be performed on test substrates not containing, at the start of the test run, the test layer. In embodiments, in each test run, the same type of test substrates may be used, typically comprising the same type of porous material.

In embodiments, each test run comprises exposing the porous material to the vapor for depositing the test layer. The vapor may comprise a precursor for the test layer, or for a component of the test layer. In embodiments, the precursor may be provided in the process chamber comprising the one or more test substrates. In embodiments, e.g., embodiments wherein the deposition process is ALD, each test run may comprise, cyclically, performing the steps of: providing a first vapor comprising a first precursor to a first component of the test layer, and providing a second vapor comprising a second precursor to a second component of the test layer. The set of test process parameters associated with the test run may be applied at least during a portion of the time frame during which the vapor deposition process for depositing the test layer is performed. The set of test process parameters associated with the test run may be applied during the complete vapor deposition process of the test run.

In embodiments, each test run may comprise vapor depositing the test layer on each of a plurality of said test substrates, stacked in a same process chamber, wherein said analysis comprises determining the effect of the set of test process parameters on the deposited test layer for different test substrates of the test run. This allows for evaluation of wafer-to-wafer variation within a batch, simulating batch vapor deposition process conditions. The substrates may be stacked in a same process chamber, in a vertical or horizontal configuration, for simultaneous or concurrent processing during the deposition step of the test run. For example, the process chamber may be a multi-wafer batch ALD system that accommodates wafers in a vertical stack, or a CVD furnace that accommodates a horizontal boat loaded with multiple substrates.

In embodiments, performing one or more test runs may comprise performing a plurality of test runs, wherein said analysis comprises determining the effect of the set of test process parameters on the deposited test layer for test substrates of different test runs. In embodiments, performing one or more test runs may comprise performing a single test run.

In embodiments, each process parameter may be any adjustable input or condition for the deposition process that influences the outcome of the vapor deposition process. In embodiments, the set of process parameters may comprise a single process parameter that is to be selected by the method. In embodiments, the set of process parameters may comprise a plurality of process parameters that are to be selected by the method. In embodiments, the set of process parameters may comprise substantially each process parameter that affects the layer to be deposited.

In embodiments, the set of process parameters may comprise a temperature, a pressure, a precursor, a partial pressure of a precursor, or a pulse time for pulsing a precursor, or combinations thereof. Said precursor may be any vapor-phase chemical entity or compound introduced into the deposition chamber that reacts or decomposes to form at least part of the deposited layer. In embodiments wherein the deposition process is performed in a batch reactor, the set of process parameters may comprise a parameter selected from a group consisting of a rotation speed of the substrates, a pitch or spacing between substrates, a configuration of the vapor injector, a pressure, a temperature, a precursor, a partial pressure of a precursor, or a pulse time for pulsing a precursor, a noble (or inert) gas purging parameter (e.g., pressure, flow rate, or purge time), a number of substrates, a configuration of the wafer boat (e.g., for comparing different wafer boat designs and compare the result), or combinations thereof.

The test runs with the test process parameters may provide a test for the deposition process with the process parameters. The test process parameters may provide a test for the process parameters. The set of test process parameters associated with each test run is preferably adapted for providing information for selecting the set of process parameters for the process for vapor depositing a layer on a surface of a structured semiconductor substrate. The set of test process parameters associated with the test runs typically provides a test on basis of which the set of process parameters for the process for vapor depositing a layer on a surface of a structured semiconductor substrate may be selected.

The set of test process parameters may correspond, with respect to type of parameters, to the set of process parameters. In embodiments, each test process parameter of each set of test process parameters may be of a same type as a process parameter of the set of process parameters that is to be selected for the process for vapor depositing a layer on a surface of a structured semiconductor substrate. In embodiments, each set of test process parameters contains, for each process parameter of the set of process parameters to be selected, a corresponding test process parameter. For example, if the set of process parameters to be selected comprises a pressure, each set of test process parameters may comprise a pressure as well. For example, if the set of process parameters to be selected comprises a temperature, each set of test process parameters may comprise a temperature as well. For example, if the set of process parameters to be selected comprises a specific design of a vapor injector, each set of test process parameters may comprise a specific design of a vapor injector as well.

In embodiments, the sets of test process parameters for different test runs may be tuned or varied. In embodiments, each type of test process parameter may independently be tuned or varied between different test runs. In these embodiments, a precursor or a design of the vapor injector may be varied for different test runs. In these embodiments, a measure may be tuned or varied, e.g., a pressure or a temperature or a partial pressure of the precursor may be different for the different test runs. For example, in a method for selecting a pressure for a process for vapor depositing a layer on a surface of a structured semiconductor substrate, multiple test runs may be performed, each test run being associated with a different magnitude for the pressure. The analysis may then reveal what pressure provides good deposition of the test layer, which may then be assumed to be a good pressure to deposit the layer in the process for vapor depositing a layer on a surface of a structured semiconductor substrate.

In some embodiments, the set of test process parameters of different test runs may be the same or identical (e.g., both with respect to type and with respect to measure). In this way, the stability or uniformity of the deposition process over several deposition runs may be assessed when using said set of test process parameters. For example, in embodiments, in a method for selecting a pressure for a process for vapor depositing a layer on a surface of a structured semiconductor substrate, multiple test runs may be performed, each run being associated with the same magnitude for the pressure. If the test pressure appears to provide good results over several test runs, that pressure may be used in the process for vapor depositing a layer on a surface of a structured semiconductor substrate. These embodiments provide assessment of run-to-run repeatability, a critical factor for high-volume manufacturing.

In embodiments, the analysis of the deposited test layer provides information on the effect of the set of test process parameters on the test layer. In embodiments, determining the effect of the set of test process parameters on the deposited test layer may comprise determining whether the test layer has a particular (e.g., bad or good) quality, or has predetermined characteristics, when applying the set of test process parameters. In embodiments, the analysis of the deposited test layer may be performed so as to determine or assess a performance or quality or result of the test deposition process, or of the test layer deposited by the test deposition process, when applying the set of test process parameters. From the analysis it may be determined that a deposited test layer of good quality is obtained by using a particular set of process parameters. From the analysis it may be determined that a deposited test layer of poor quality is obtained by using a particular set of process parameters. From the analysis it may be determined that particular properties or characteristics of the deposited test layer fall within, or do not fall within, a predetermined range, e.g., whether minimum specs are met by applying the set of test process parameters. The effect of individual process parameters on the deposited test layer may be determined. The effect of multiple process parameters combined on the deposited test layer may be determined. The effect of the (e.g., complete) set of process parameters combined on the deposited test layer may be determined.

In embodiments, said analysis comprises determining a thickness, a standard deviation of said thickness, a difference in said thickness between different locations of the deposited layer in the pores, a composition, or combinations thereof, of the deposited test layer. In embodiments, determining an effect of the set of test process parameters on the deposited test layer may comprise determining an effect of the set of test process parameters on one or more characteristics or properties of the deposited test layer. Said properties of the deposited test layer may be a thickness, a standard deviation of said thickness, a difference in said thickness between different locations of the deposited layer in the pores, or a composition, of the deposited test layer. Said analysis may comprise determining an effect of the set of test process parameters on each of said properties.

In embodiments, said analysis may comprise determining the effect of the set of test process parameters on the test layer deposited in a pore or in pores of the porous material, e.g., deposited on a surface of a pore or on surface of pores of the porous material. In embodiments, the analysis of the deposited test layer may be performed so as to determine or assess a performance or quality or result of the test layer deposited by the test deposition process on a surface of the pores, when applying the set of test process parameters. This enables evaluation of how the deposition process performs on high-aspect-ratio features similar to those on the structured semiconductor substrate. This may provide information on the deposition process in the pores, e.g., whether a uniform layer may deposited within the pores, and, correspondingly, on the structured semiconductor substrate surface. This may enable probing the vapor flow through small voids, which may give a good estimate of how the vapor flows through voids that may be present on the structured semiconductor substrate, such as gaps (e.g., between structures or devices on the structured semiconductor substrate), trenches, or holes, such as via holes or through holes.

In embodiments, the analysis may be performed on the deposited test layer at different locations. Thereby, a property of the test layer at different locations may be compared. In embodiments, the test layer may be analyzed at different locations along a pore. In these embodiments, the test layer may be analyzed at an entrance of a pore and at a bottom the pore. Thereby, the analysis may provide information on the effect of the test parameter on the flow of the vapor through narrow gaps. In embodiments, the test layer may be analyzed at a pore at the center of the porous material of the test substrate and at a pore on the edge of the porous material of the same test substrate. In embodiments, the test layer may be analyzed at a pore of the porous material of a test substrate at a center of a wafer boat and of a test substrate on a top or bottom position of the boat. Thereby, the effect of the test parameter on the test layer deposited on surfaces of pores on different substrates within a stack of layers may be assessed.

In embodiments, the analysis may comprise performing scanning electron microscopy imaging, transmission electron microscopy imaging, a mass variation measurement, or an ellipsometry measurement. These analytical techniques may provide detailed information about layer properties at various locations and depths within the porous structure.

The layer deposited on the surface of the porous material may be determined by a direct measurement on the test layer on a surface of a porous material. However, that is not necessary and instead, properties of the test layer on a surface of a porous material may be indirectly determined. In embodiments, over, and separated from, the porous material of the test substrate, a flat surface may be provided during the test run, wherein the porous material is separated from the flat surface by a gap through which the vapor may move. The flat surface may be that of another substrate, which may be any type of substrate: said substrate may be of the same type as the test substrates if said test substrate contains a flat surface (in addition to the porous surface of the porous material: for example, the flat surface may be a bottom surface of the substrate, and the porous material may be at a top surface of the substrate), but this is not required. In the vapor deposition process of the test run, the vapor may be deposited on surfaces of the porous material, and, in the process, the vapor may also be deposited on the flat surface. Properties of the test layer, thus deposited on the flat surface, may be influenced by the porous material, so that determining the effect of the set of test process parameters on the properties of the test layer deposited on the flat surface may provide information on the effect of the set of test process parameters on the properties of the test layer deposited on the porous material. Measuring properties of the test layer deposited on the flat surface, may be faster and more straightforward than measuring properties of the test layer deposited on a surface in the pores of the porous material.

As one example, each test run may be performed on a stack of test substrates, each substrate comprising the porous material at a top surface, and a flat bottom surface. If the vapor-phase precursor used for the vapor deposition completely saturates the surface of the porous material (that is, closing the pores of the porous material with the deposited test layer) across the whole test substrate, then deposition on the flat bottom surface of the test substrate above will be uniform. If there is no saturation, then there will be more deposition on the flat surface, at a side of the porous material away from the center of the porous material, than on the flat surface, directly above the center of the porous material, as the precursor gets depleted as it flows from the part of the gap at the side of the porous material towards the part of the gap at the center of the porous material. For example, ellipsometry of the deposited test layer on the flat surface above the porous material may be a quick way to have an idea of the saturation, which is not as expensive or complicated as TEM on the test layer deposited on the surface of the porous material.

Typically, based on said analysis, the set of process parameters is selected. In embodiments, a set of process parameters is selected for which the deposited layer has, or may (based on said analysis) be expected to have, a particular (e.g., good) quality or predetermined properties, such as a predetermined composition, uniformity, or thickness. In embodiments, the selected set of process parameters may be selected amongst the one or more sets of test process parameters. For example, the selected set of process parameters may be identical to a set of test process parameters providing good or optimal properties to the test layer. However, this is not essential. In embodiments, the selected set of process parameters may be derived by extrapolation or interpolation from the sets of test process parameters.

Any features of any embodiment of the first aspect may be independently as correspondingly described for any embodiment of any of the other aspects of the present invention.

In a second aspect, the present invention relates to a process of vapor depositing a layer on a surface of a structured semiconductor substrate, the method containing: selecting a set of process parameters using a method in accordance with the first aspect, and vapor depositing the layer on the surface of the structured semiconductor substrate using, i.e., applying, the selected set of process parameters.

In embodiments, the structured semiconductor substrate may be provided in a process chamber, which may be the same process chamber or the same type of process chamber as that in which the test runs were performed, but this is not essential. In embodiments, the process is for vapor depositing a layer on a surface of each of a plurality of structured semiconductor substrates. In embodiments, a stack of structured semiconductor substrates, e.g., stacked in a wafer boat, may be provided in the process chamber.

In embodiments, the step of vapor depositing the layer on the surface of the structured semiconductor substrate comprises exposing the structured surface of the structured semiconductor substrate to the vapor for depositing the layer. The vapor may comprise a precursor to the layer, or to a component of the layer. In embodiments, the precursor may be provided in the process chamber comprising the one or more structured semiconductor substrates. In embodiments, e.g., embodiments wherein the deposition process is ALD, vapor depositing the layer may comprise, cyclically, performing the steps of: providing a first vapor comprising a first precursor to a first component of the layer, and providing a second vapor comprising a second precursor to a second component of the layer. The process parameters may be applied at least during a portion of the time frame during which the vapor deposition process for depositing the layer is performed. The process parameters associated with the test run may be applied during the complete vapor deposition process.

In embodiments, the surface of the structured semiconductor substrate may contain a void, wherein a pore of the porous material of each test substrate may have a diameter or width—e.g., a mean diameter or mean width along the pore—within 50%, preferably within 20%, more preferably within 10%, of a dimension, e.g., a width, of the void. The analysis may comprise determining the effect of the set of test parameters on the test layer deposited on a surface of said pore having a diameter similar to a width of the void. In embodiments, the surface of the structured semiconductor substrate may contain a void, wherein pores of the porous material of each test substrate have a mean diameter or mean width (e.g., mean along each pore and/or mean amongst the different pores) within 50%, preferably within 20%, more preferably within 10%, of a dimension, e.g., a width, of the void. This close matching of dimensions ensures the test conditions accurately reflect the transport limitations in the actual product structures. However, such a close matching of dimensions is not essential, as, independent of the relative dimensions, the pores typically provide an area enhancement that, on itself, may provide a good simulation of the structured semiconductor substrate, e.g., compared to the flat test substrates of the state of the art.

In embodiments, the surface of the structured semiconductor substrate may contain a void, wherein a mean pore depth of the porous material is at least as large as a depth of the void. This ensures that the test adequately evaluates the challenging aspects of deep feature filling in the actual product.

Any features of any embodiment of the second aspect may be independently as correspondingly described for any embodiment of any of the other aspects of the present invention.

In a third aspect, the present invention relates to an assembly comprising: a vapor deposition apparatus configured for performing one or more test runs, each test run being associated with a set of test process parameters, each test run comprising: vapor depositing, applying the associated set of test process parameters, a test layer on a surface of a porous material of each of one or more test substrates, and a device configured for analysing the deposited test layer of each of the one or more test substrates of each of the one or more test runs for determining an effect of the set of test process parameters on the deposited test layer, and a controller configured for selecting, based on said analysis, the set of process parameters for a process for vapor depositing a layer on a surface of a structured semiconductor substrate.

The controller may be configured, e.g., may comprise instructions, for applying, during each test run, the test process parameters associated with said run.

The device configured for analysing the deposited test layer may be any device suitable for analysing the deposited test layer, e.g., any device suitable for determining the effect of the set of test parameters on the deposited test layer. The controller may control said device. The controller may comprise a processor for performing said analysis.

Any features of any embodiment of the third aspect may be independently as correspondingly described for any embodiment of any of the other aspects of the present invention.

### Example of Selecting a Set of Process Parameters

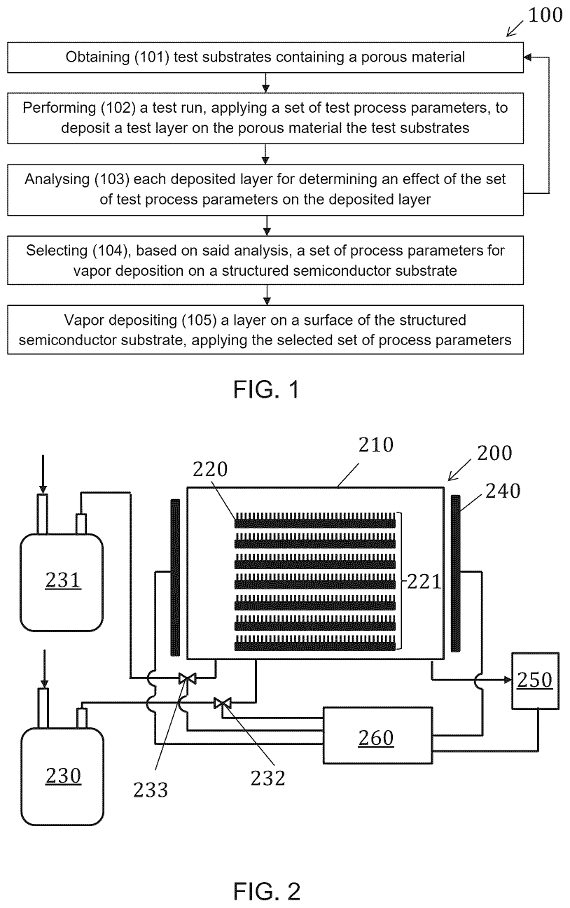

FIG. 1 illustrates a block diagram of a method (100) for selecting a set of process parameters for vapor deposition on structured semiconductor substrates. In what follows, an exemplary method in accordance with embodiments of the present invention is detailed with reference to FIG. 1.
FIG. 2 is a schematic representation of a vertical batch furnace (200) used for vapor deposition according to embodiments of the present invention. The vertical batch furnace comprises a process chamber (210) capable of accommodating a stack (221) of substrates (220) arranged in a vertically stacked configuration. The exemplary furnace includes vapor sources (230, 231) for introducing precursor gases and purge gases into the chamber (210), which are coupled to the process chamber (210) via valves (232, 233) that are controlled by a controller (260). A heating system (240) for controlling a process temperature in the process chamber (210) is controlled by the controller (260) as well. The controller (260) further controls a pressure device, e.g., a vacuum system (250), for controlling a process pressure in the process chamber (210). The vertical batch furnace (200) may be configured to perform vapor deposition processes, preferably atomic layer deposition, on each substrate (220) of the stack (221) simultaneously under controlled conditions of temperature, pressure, and gas flow.

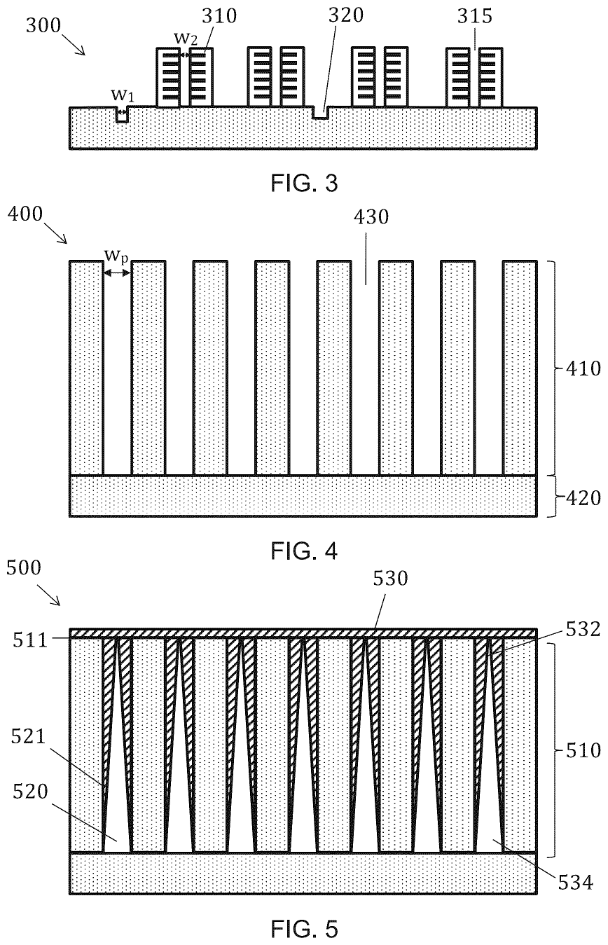

FIG. 3 depicts a cross-sectional view of a structured semiconductor substrate (300) on which a layer is to be deposited by a vapor deposition process. For this process, the vertical batch furnace (200) of FIG. 2 may be used. For this process, a set of process parameters is to be selected.

The structured semiconductor substrate (300) contains structural features that provide a surface area enhancement, compared to a flat substrate, to the substrate (300). In the present example, the structural features comprise intermediates in the formation of devices, in particular VNAND structures (310), and via holes (320). The VNAND structures (310) comprise multiple alternating layers forming high aspect ratio features, separated from each other by narrow voids or gaps (315). The via holes (320) extend deeply into the substrate with narrow openings. However, the invention is not limited to these particular structural features, and the structured semiconductor substrate (300) could contain further or different features resulting in a surface area enhancement.

Conventional process parameters developed using flat substrates may not provide adequate coverage or conformality when applied to such highly structured substrates. Therefore, in embodiments of the present invention, test substrates containing a porous material are used for testing process parameters.

As such, the method comprises obtaining (101) test substrates containing a porous material (cfr. FIG. 1). FIG. 4 is a cross-sectional view of an exemplary test substrate (400) that may be used in embodiments of the method of the present invention, containing a porous material comprising an anodized aluminum oxide layer (410) in accordance with embodiments of the present invention. The exemplary test substrate (400) further includes a base substrate (420), which may be silicon or aluminum, that is covered with the nanoporous aluminum oxide layer (410).

In the example illustrated, the nanoporous aluminum oxide layer (410) contains a plurality of dead-end pores (430) with nanometric opening radius and micrometric pore depth, packed in a uniform way with controlled reproducible geometrical parameters. The pore width or pore diameter (wₚ) of at least some of the pores may be selected to be similar to the size or width of at least some of the voids—e.g., the width (w₁) of the via holes (310) or the width (w₂) of the void (315) between the VNAND structures (310) may be within 50%, preferably within 30%, more preferably within 10%, of the mean pore width (wₚ)—of the structured semiconductor substrate shown in FIG. 3, allowing the test substrate (410) to mimic the surface area enhancement and gas flow paths of the structured semiconductor substrate (300).

Before depositing said test layer, the surface of the porous aluminium oxide (300) may be coated (not shown) by a material of a type present at a surface of the structured semiconductor substrate. For example, the surface of the structured semiconductor substrate (300) may contain silicon oxide, and the surface of the porous aluminium oxide may be coated by silicon oxide to mimic the surface of the structured semiconductor substrate (300). This may provide a more realistic test environment that matches the actual production substrate surface.

Subsequently, the method contains performing (102) one or more test runs, each test run being associated with a set of test process parameters. The test runs may be performed in the same vertical batch furnace (200) in which the structured semiconductor substrate (300) is to be processed (cfr. FIG. 1), but this is not required. In the present example, a stack of test substrates is introduced into the vertical batch furnace (200). In the present example, for each test run, a set of test process parameters is selected that provides information for selecting the set of process parameters for depositing the layer on the structured semiconductor substrate (300). Each test run includes vapor depositing a test layer on a surface of a porous material of one or more test substrates while applying the associated set of test process parameter.

When the test runs are performed in the vertical batch furnace (200) of FIG. 2, the controller (260) may apply, in each test run, the set of test process parameters associated with that test run. The set of test process parameters may, for example, contain a pressure, in which case the controller (260) may induce the pressure device (250) to apply said pressure in the process chamber (210). The set of test process parameters may, for example, comprise a process temperature, in which case the controller (260) may induce the heating system (240) to apply said process temperature to the process chamber (210). The set of test process parameters may, for example, comprise a precursor. The controller (260) may control the corresponding valve (232, 233) so that the precursor associated with the test run is provided into the process chamber (210). Alternatively, a particular vapor source (230, 231) for providing the precursor associated with the test run may be provided. The set of test process parameters may, for example, comprise a partial pressure of the precursor. In that case, the controller (260) may control the valve (232, 233) so as to provide the corresponding partial pressure of the precursor into the process chamber (210).

FIG. 5 shows a cross-sectional view of a test substrate (500) after a first test run applying a first set of test process parameters, which may comprise a first pressure, a first process temperature, a first precursor, and a first partial pressure for the first precursor, and which may be applied by the controller (260). The test substrate (500) includes the porous aluminum oxide layer (510) as described in FIG. 4. A deposited test layer (530) is visible on the top, porous surface (511) and on surfaces (521) within the pores (520) of the test substrate.

The method contains analyzing (103) (cfr. FIG. 1) the deposited test layer (530) to determine an effect of the set of test process parameters on the deposited test layer (530). In the present example, the analysis of the deposited test layer (530), deposited in the first test run, shows that the test layer (530) exhibits a non-conformal thickness profile, with the layer being substantially thicker at the top or entrance (532) of the pores (520) than at the bottom (534) of the pores (520). This non-uniform thickness distribution indicates that flow of the vapor through the pores (520), i.e., through the high surface area enhancement material, may be poor when applying the first set of test process parameters.

These results suggest that modifications to process parameters such as temperature, pressure, precursor selection or partial pressure may be needed to improve conformality. Therefore, different test substrates may be obtained (101) on which a second test run may be performed (102), wherein the test process parameters for the second run may be tuned compared to the test parameters of the first test run. For example, at least one of the test process parameters for the second test run may be adapted, compared to the test process parameters for the first test run, based on the analysis of the test layer deposited in the first run. For example, the second set of test process parameters may comprise a second pressure, a second process temperature, a second precursor, and a second partial pressure for the second precursor, which may be applied by the controller (260).

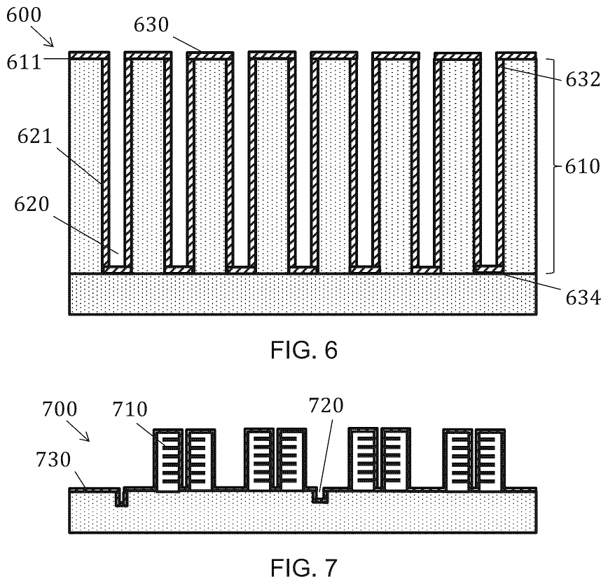

FIG. 6 depicts a cross-sectional view of another test substrate (600) after the second test run applying the second set of test process parameters, different from the first set. The test substrate (600) in the second test run is of the same type, and has substantially the same features, as the test substrate used in the first test run, i.e., includes the porous aluminum oxide layer (610) with pores (620). A deposited test layer (630) is visible on the top, porous surface (611) and on surfaces (621) within the pores (620) of the test substrate (600).

In contrast to FIG. 5, the analysis (103) on the test layer (630) formed in the second run shows that this test layer (630), formed by a vapor deposition process applying the second set of test process parameters, exhibits a conformal thickness throughout the pores (620), with the test layer thickness at the top or entrance (632) of the pores (620) being substantially equal to the thickness at the bottom (634) of the pores (620). This uniform thickness distribution indicates that flow of the vapor through the pores may be significantly improved when applying the second set of test process parameters, suggesting that these parameters may be suitable for application to the vapor deposition process for depositing the layer on the structured semiconductor substrate.

Based on the analyses of the test layers (532, 632) of the test runs, in the method of embodiments of the present invention, a set of process parameters is selected (104) for vapor depositing a layer on the surface of a structured semiconductor substrate.

Subsequently, applying the selected set of process parameters, the layer may be vapor deposited (105) on each of a plurality of structured semiconductor substrates (700), applying the selected set of process parameters in the vertical batch furnace (200) of FIG. 2. FIG. 7 illustrates the structured semiconductor substrate (700) of FIG. 3 after performing vapor deposition using the set of process parameters selected based on the test runs performed on the test substrates. In the present example, the deposited layer (730) covers the structures, i.e., the surfaces of the VNAND structures (710) and via holes (720). The layer exhibits conformal coverage throughout the complex topography of the substrate, with uniform thickness on the tops, sidewalls, and bottoms of the structures. This demonstrates that the process parameters selection method using the nanoporous test substrates has successfully identified parameters that provide the desired conformality for the actual product substrate.

It is to be understood that although preferred embodiments, specific constructions and configurations, as well as materials, have been discussed herein for devices according to the present invention, various changes or modifications in form and detail may be made without departing from the scope of this invention. Functionality may be added or deleted from the block diagrams and operations may be interchanged among functional blocks. Steps may be added or deleted to methods described within the scope of the present invention.

1.- A method of selecting a set of process parameters for a process for vapor depositing a layer on a surface of a structured semiconductor substrate, the method containing:
performing one or more test runs, each test run being associated with a set of test process parameters, each test run comprising:
vapor depositing, applying the associated set of test process parameters, a test layer on a surface of a porous material of each of one or more test substrates, and
analysing the deposited test layer of each of the one or more test substrates of each of the one or more test runs for determining an effect of the set of test process parameters on the deposited test layer, and
selecting, based on said analysis, the set of process parameters for said process for vapor depositing the layer on the surface of the structured semiconductor substrate.

2.- The method of claim 1, wherein a surface area enhancement of a surface of the porous material is at least 10×, preferably at least 50×, with respect to a flat surface.

3.- The method of claim 1, wherein a surface area enhancement of the porous material is higher than a surface area enhancement of the structured semiconductor substrate.

4.- The method of claim 1, wherein the porous material is porous aluminium oxide.

5.- The method of claim 4, wherein the test substrate contains an aluminium substrate covered by the porous aluminium oxide.

6.- The method of claim 4, wherein-before depositing said test layer-the surface of the porous aluminium oxide is coated by a material of a type present at a surface of the structured semiconductor substrate.

7.- The method of claim 1, wherein the set of process parameters comprises a temperature, a pressure, a precursor, a partial pressure of a precursor, or a pulse time for pulsing a precursor, or combinations thereof.

8.- The method of claim 1, wherein said analysing comprises determining the effect of the set of test process parameters on the test layer deposited in pores of the porous material.

9.- The method of claim 1, wherein said analysing comprises determining a thickness, a standard deviation of said thickness, a difference in said thickness between different locations of the deposited layer, a composition, or combinations thereof, of the deposited test layer.

10.- The method of claim 1, wherein each test run comprises vapor depositing the test layer on each of a plurality of said test substrates, stacked in a same process chamber, wherein said analysis comprises determining the effect of the set of test process parameters on the deposited test layer for different test substrates of the test run.

11.- The method of claim 1, wherein performing one or more test runs comprises performing a plurality of test runs, wherein said analysis comprises determining the effect of the set of test process parameters on the deposited test layer for test substrates of different test runs.

12.- The method of claim 1, wherein the analysis comprises performing scanning electron microscopy imaging, transmission electron microscopy imaging, a mass variation measurement, or an ellipsometry measurement.

13.- The method of claim 1, wherein pores of the porous material have a mean diameter of from 1 to 100 nanometers.

14.- The method of claim 1, wherein pores of the porous material have a mean depth of at least 1 micrometer.

15.- The method of claim 1, wherein the process for vapor depositing is chemical vapor deposition, preferably atomic layer deposition.

16.- The method of claim 1, wherein the structured semiconductor substrate comprises a semiconductor device or an intermediate in the formation of a semiconductor device.

17.- A process of vapor depositing a layer on a surface of a structured semiconductor substrate, the method containing:
selecting a set of process parameters using a method in accordance with claim 1, and
vapor depositing the layer on the surface of the structured semiconductor substrate using the selected set of process parameters.

18.- The process of claim 17, wherein the surface of the structured semiconductor substrate contains a void, wherein pores of the porous material have a mean diameter within 50%, preferably within 20%, more preferably within 10%, of a dimension of the void.

19.- The process of claim 17, wherein the surface of the structured semiconductor substrate contains a void, wherein a mean pore depth of the porous material is at least as large as a depth of the void.

20.- An assembly comprising:
a vapor deposition apparatus configured for performing one or more test runs, each test run being associated with a set of test process parameters, each test run comprising:
vapor depositing, applying the associated set of test process parameters, a test layer on a surface of a porous material of each of one or more test substrates, and
a device configured for analysing the deposited test layer of each of the one or more test substrates of each of the one or more test runs for determining an effect of the set of test process parameters on the deposited test layer, and a controller configured for selecting, based on said analysis, a set of process parameters for a process for vapor depositing a layer on a surface of a structured semiconductor substrate.
